(19) United States
(12) Patent Application Publication
(10) Pub. No.: US 2007/0103876 A1
(43) Pub. Date: May 10, 2007

(54) MINIATURIZED FORM FACTOR WIRELESS COMMUNICATIONS CARD FOR GENERIC MOBILE INFORMATION DEVICES

(75) Inventors: William X. Huang, San Ramon, CA (US); Shanquan Bao, Alameda, CA (US); Guang Wan, Fremont, CA (US); Liming Gao, Alameda, CA (US); JingChun Sun, Beijing (CN)

Correspondence Address: FELIX L. FISCHER, ATTORNEY AT LAW, 1607 MISSION DRIVE, SUITE 204, SOLVANG, CA, 93463, US

(73) Assignee: UTStarcom, Inc., Alameda, CA (US)

(21) Appl. No.: 11/308,221

(22) Filed: Mar. 13, 2006

Related U.S. Application Data
(60) Provisional application No. 60/597,110, filed on Nov. 10, 2005.

(51) Int. Cl. H05K 1/14

(52) U.S. Cl. 361/737

(57) ABSTRACT

A miniaturized form factor card provides a communications system for mobile information devices having an applications processor and user interface components. A receiving frame is provided in the mobile information device and an insertable miniaturized form factor card incorporating means for RF transmission and reception and a wireless modem and having an indexing connector which is received in a mating moiety in the receiving frame. The applications processor and the user interface components in the mobile information device are interconnected to digital functions of the wireless modem and means for RF transmission and reception through the connector. Additionally, the miniaturized form factor card further includes a power management function interfacing with the applications processor and user interface components through the connector.

### REFERENCE TO RELATED APPLICATIONS

This application claims priority of United States Provisional Application Ser. No. 60/597110 filed on Nov. 10, 2005 having the same title as the present application.

### BACKGROUND OF THE INVENTION

1. Field of the Invention

This invention relates generally to the field of operating platforms for mobile phones and personal data systems and more particularly to a wireless communications card with a miniaturized form factor which is insertable into generic mobile information devices to accommodate desired wireless communication functions.

2. Related Art

Current design time-to-market for mobile phone and personal information devices is extended due to current design philosophy and practice. Turn-around time for a typical complete handset design is about 9 months. Currently terminal vendors need to spend significant amount of resources on basic wireless communication functions and cannot concentrate on truly value-added design works, such as industrial design and software applications. It is also difficult to develop multiple models with significant differences based on a common printed circuit board (PCB) platform. Traditional wireless devices using discrete solution have difficulty supporting multiple band or modes such as GSM, CDMA, 3G. Discrete chipset solutions consume at least three times more PCB space. There are significant financial and technical barriers of entry for new companies without significant resources, or established companies without wireless expertise.

Currently there are some vendors selling modules that can provide wireless communication functions in a particular wireless technology. However these modules are large in size with proprietary interfaces. These modules require significant amount of vendor integration. Alternatively, certain prior art systems are simply modularizing wireless modem functions. Prior art systems for removable cartridges providing communications elements such as that disclosed in U.S. Pat. No. 6,690,947 to Tom provide some flexibility in applications design; however, such systems were bulky and lacked packaging and connector innovations required for practical application of such systems.

It is therefore desirable to provide a system that can save RF tuning, debugging and certification thereby reducing design lead time significantly. It is also desirable that a system be provided with the ability to integrate hardware, software, utilities and drivers which will allow true plug and play functionality for end users or mobile information device design houses. It is desirable to provide functional capability through an insertable card to eliminate the requirement for a separate CPU or applications processor in the mobile information device. Additionally, it is desirable that a system be provided with a complete modem solution that will support multi-mode and multi-band. It is also desirable that a system be provided with space savings and weight reduction to permit more compact portable devices and flexible designs and integrate chipset and passive components into a common module. It is desirable that such a common module be employed to reduce the total number of solder joints, thus increasing the reliability of the final product. It is desirable to provide a system to turn the currently complex design work for wireless enabled device into much simpler product integration to lower the barriers of entry significantly for all new entrants. Finally, it is desirable to provide a wireless communications card installable in generic mobile information devices by an end user.

### SUMMARY OF THE INVENTION

The present invention provides a wireless communications card for mobile information devices with user interface components and having in certain embodiments an applications processor. A receiving frame is provided in the mobile information device and an insertable miniaturized form factor card incorporating means for RF transmission and reception and a wireless modem and having an indexing connector which is received in a mating moiety in the receiving frame. The applications processor, the user interface components, or both in the mobile information device are interconnected to digital functions of the wireless modem and means for RF transmission and reception through the connector. Additionally, the miniaturized form factor card further includes a power management function interfacing with the applications processor and user interface components through the connector.

### BRIEF DESCRIPTION OF THE DRAWINGS

These and other features and advantages of the present invention will be better understood by reference to the following detailed description when considered in connection with the accompanying drawings wherein:

FIG. 1 is an exploded view of a miniaturized form factor card employing the present invention and an exemplary mobile information device;

FIG. 2 is a block diagram of the elements of an exemplary embodiment of a miniaturized form factor card;

FIG. 3a is a block diagram of the interaction between an applications processor and other mobile information device functions with the elements of the miniaturized form factor card;

FIG. 3b is a block diagram of the interaction between the applications processor and other mobile information device functions with the elements of a multimode version of the miniaturized form factor card;

FIG. 3c is a block diagram of the elements of the inventions with exemplary communications buses;

FIGS. 4a and 4b are schematic side and top views of the mounting frame and connector elements for a miniaturized form factor card according to the present invention;

FIGS. 4c and 4d are schematic side views of the embodiment of FIGS. 4a and 4b with the card prepared for installation and the card installed;

FIGS. 5a and 5b are schematic side views of the installation of an alternative embodiment for the mounting frame and connector elements for a miniaturized form factor card according to the present invention;

FIG. 6a is a side view of indexing locations of connector elements for the embodiments disclosed in FIGS. 4a-4d and 5a and 5b;

FIG. 6b is a top view of mechanical indexing elements in the mounting frame;

FIGS. 6c-6e are top views of the mechanical indexing elements of the miniaturized form factor card for use with the frame of FIG. 6b;

FIG. 6f is a top view of the mounting frame and connector elements for an alternative embodiment with a dual elastomeric connector arrangement;

FIG. 7 is an isometric view of a third embodiment of a miniaturized form factor card according to the present invention employing an alternative connector configuration;

FIG. 8a is an pictorial view of a the embodiment of a miniaturized form factor card according to the present invention employing the alternative connector configuration of FIG. 7;

FIG. 8b is an isometric view of a fourth embodiment of a miniaturized form factor card according to the present invention employing an alternative connector configuration;

FIG. 9 is a schematic representation of the various mobile information devices for which the miniaturized form factor card employing the present invention would be applicable.

### DETAILED DESCRIPTION OF THE INVENTION

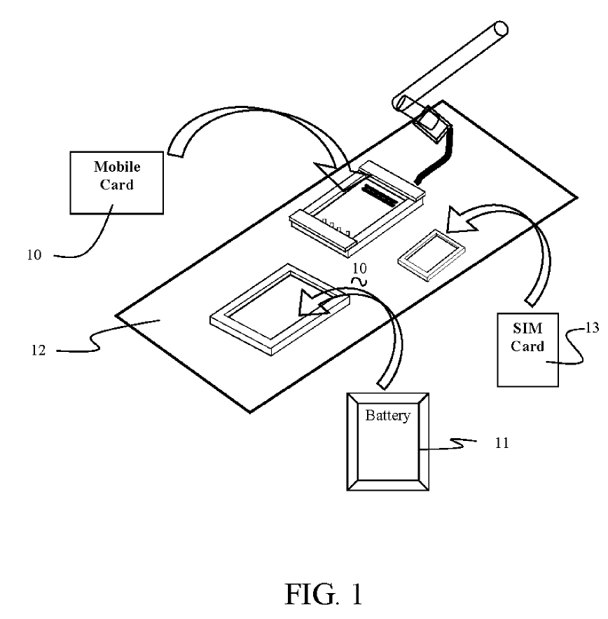

FIG. 1 demonstrates one embodiment of the present invention with a miniaturized form factor card 10 according to the invention shown exploded from the mobile information device printed circuit board 12 in which it is to be installed. Battery 11 and Subscriber Identity Module (SIM) 13 elements are also shown for reference. For the drawing, a mobile phone is shown as the mobile information device (MID). FIG. 2 shows an exemplary block diagram of the functional elements of the card of FIG. 1. In an exemplary embodiment, the form factor of the card is comparable to a secure digital (SD) card having a substantially rectangular dimensional planform of about 24 by 32 mm with a thickness of about 2-3 mm. The communications elements included in the card are an RF integrated circuit 14, a wireless broadband modem 16, a memory 18 for use by the processing elements of the modem and RF circuits and a power management integrated circuit 20. An exemplary pin layout for a bump technology interface integrated into the bottom of the card provides connection elements 22 for the RF circuit, a connection block for the power and ground requirements 24, a set of connector elements interface with the applications processor 26 including a test interface and a set of connector elements to interface with the handset peripherals 28 including the keypad 30, display 32 and other basic handset functions for user interface.

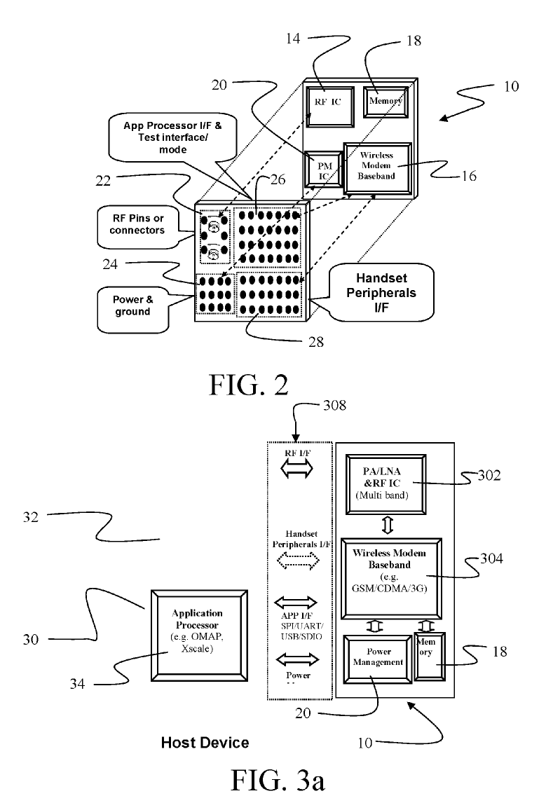

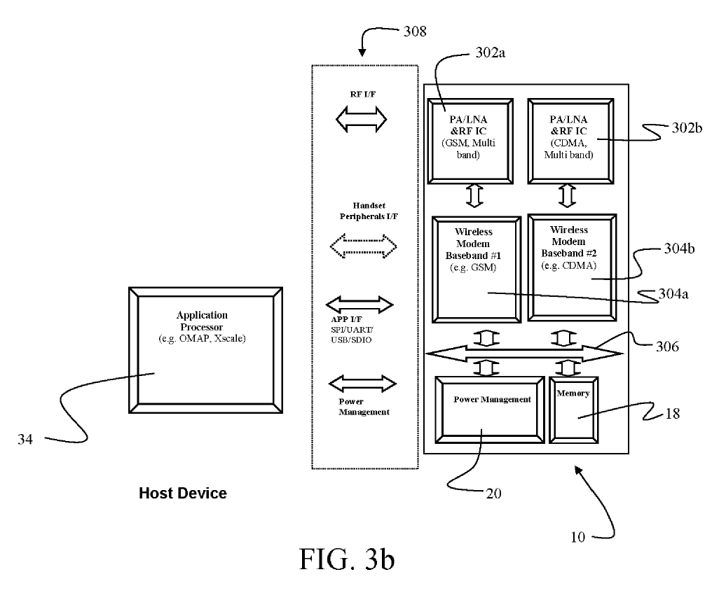

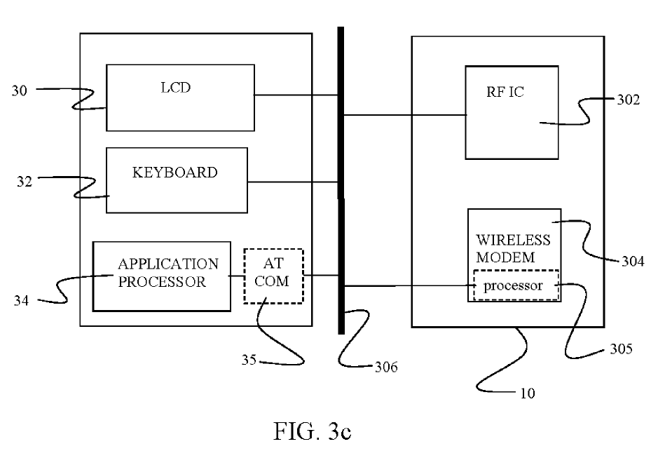

The miniaturized form factor card provides all of the elements for a desired communication technology such as Personal HandyPhone System (PHS), Code Division Multiple Access (CDMA), Global System for Mobile communications (GSM), WiMax, wireless LAN, Digital Video Broadcast—Handheld (DVB-H) or Universal Mobile Telecomunications System (UMTS), including single or multiband. The technology can be included as single or multiple mode technologies in certain applications. The handset design can then concentrate on the human factor interface elements and the non-communication functions desired for the device. As shown in FIG. 3a, the applications processor 34 for the mobile information device such as those produced by Texas Instruments, Inc. or Intel, Inc. or other manufacturers provides the desired functionality of the mobile information device and interface with the elements of card 10 for communications enablement. For the embodiment shown, a Power Amplifier/Low Noise Amplifier (PA/LNA) and RF circuit 302 is provided for a multiband communications protocol with associated modem 304. Communication with the peripherals and applications is provided through interface 308 through SPI, UART, USB, and/or SDIO. In certain applications, the base band processor in the modem in the card allows elimination of a separate CPU or applications processor in the mobile information device.

As shown in FIG. 3b, the miniaturized form factor card employs multimode capability in certain embodiments providing communications capability in multiple protocols. For the embodiment shown, a PA/LNA and RF circuit is provided for GSM 302a and CDMA 302b with associated modems 304a and 304b. A common bus 306 provides for communication with the peripherals, and applications interface as with the prior described embodiment.

Communication between the modem 304 and RF functions 302 of the miniature form factor card and the mobile information device is accomplished in exemplary embodiments using a common bus 306. Processing functions specific to the MID are accomplished by the application processor 34 while communications functions are accomplished by the processor 305 in the modem on board the card as shown in FIG. 3c. As will be described in greater detail subsequently, certain embodiments use the processor only in the MID or card as the controlling processor.

A pin out support matrix is provided in Table 1 for two exemplary embodiments of the card for applications supporting a modem in the card only or for a “handset core” application supporting all the peripherals of the MID. A 49 pin connector is employed in exemplary embodiments of the modem only functionality while a 70 pin connector is employed in the exemplary embodiment of a handset com. In the modem only mode, the operations related to the LCD and keypad are accomplished by the processor in the MID.

TABLE 1

| Type | Modem only | Handset Core |
|---|---|---|
| Total Pin Count | 49 | 70 |
| Black White LCD IF | N/A | Support |
| 8 Bit Color LCD IF | N/A | Support |
| Keypad IF | N/A | Support |
| Audio(Mic, Spkr, Earphone) IF | Support | Support |
| SIM IF | Support | Support |
| USB IF | Support | Support |
| UART IF | Support (2) | Support (1) |
| 4 bit SDIO IF | Support | N/A |
| RF IF | Support | Support |
| GPS and Second RF IF | Support | N/A |
| Power and Ground | Support | Support |
| GPIO reserve | Support | Support |

Table 2 shows an exemplary keypad communications definition for the card to employ the MID keypad for operating the functions of the card. The keys defined in column KO4 are reserved based on additional function keys present on certain keypad arrangements. A standard matrix keypad communication designation allows the card to function with MID keypads without being MID specific. MIDs operable with the card employ the standard matrix arrangement to allow interoperability and interchangeability of cards to obtain desired communications functionality. For example, one MID employs a CDMA capable card or a GSM capable card as desired with the user merely exchanging the card. The Handset Core embodiment using the 70 pin connector is employed in the example.

The 5×5 matrix shown is solely exemplary and alternative embodiments employ keypad capability as available. For the exemplary embodiment, the MID power key is connected to the card through pin 62. A “Flip detect” is provided through pin 4. Additionally, for MIDs employing the miniature form factor card, dedicated keys may be provided in certain embodiments that do not have functionality in the MID or its applications and are dedicated solely for the card functions. These keys are directly connected to the card through available pin connections.

TABLE 2

| | KO0 | | | KO3 | |
|---|---|---|---|---|---|
| | (Pin | KO1 | KO2 | (pin | KO4 |
| | 60) | (Pin 59) | (pin 58) | 57) | (pin 56) |
| KI0(pin10) | Up | Talk/Send | 3 | 7 | Center/ |
| | | | | | Menu/OK |
| KI1(pin | Down | End | 1 | 2 | Reserved |
| 11) | | | | | |
| KI2(pin12) | Left | 4 | 5 | 6 | Reserved |
| KI3(pin | Right | 8 | 9 | * | Reserved |
| 13) | | | | | |
| KI4 | 0 | Right_Select | Left_Select | # | Clear |
| (pin14) | | | | | |

For MIDs employing applications processors with higher level capability requiring Modem only functionality in the miniature form factor card, keypad communication directly with the card is not required and communications between the MID and the card are accomplished in an exemplary embodiment using a standard AT command structure 35 (as defined by Hayes and also known as Attention Code) as represented in FIG. 3c. The applications processor in the MID communicates predetermined commands for wireless communications functionality to the card.

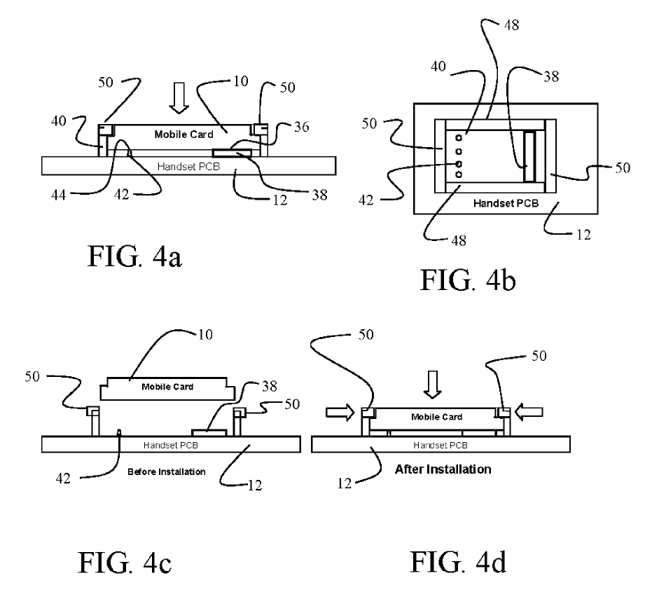

The card according to the present invention employs connector technologies and indexing arrangements for simplified installation such that mobile interface device designers can provide a common platform for multiple systems without custom design of the communication electronics. The installation could be accomplished by the end user in certain operational scenarios. A first embodiment of a connector system as contemplated by the present invention is shown in FIGS. 4a-4d. Card 10 incorporates a first elastomeric connector 36 received in a mating moiety 38 within a frame 40 mounted to PCB 12 in the handset. An exemplary elastomeric connector is a STAX connector produced by Tyco for digital interconnections as previously described. A second connection system is employed for RF and power pins using spring probe type pins 42 for the embodiment shown, such as PoGo pins produced by Emulation, which are received in mating moieties in the card undersurface 44. The card is installed in the mobile device by insertion vertically within frame 40 that receives the external edges 46 of the card. The connector arrangement provides for connection orientation of the card in the frame. Shaped indexing elements in the case of the card are employed in certain embodiments to assure proper orientation or facilitate viewing of the proper orientation during installation when the connectors may be obscured and assure insertion only in a compatible mobile information device. Opposing side edges 48 of the frame (as best seen in FIG. 4b) provide proper alignment of the card within the frame for engagement of the connectors. As best seen in FIGS. 4c and 4d, the frame incorporates retractable mechanical slides 50 which are opened to receive the card and received in reliefs 52 in the card upper surface to secure the card when installed. The mechanical frame is integrated with the handset mechanical frame in certain embodiments eliminating the necessity for an individual stand alone frame. The frame and slide arrangement in combination with the connector moieties on the undersurface of the card provide for a minimum vertical profile for the installation which is no greater in height than the thickness of the card.

An alternative embodiment of the frame receiving the card is shown in FIGS. 5a and 5b. As with the embodiment shown in FIGS. 4a-4c, this embodiment employs separate RF and power connection and digital connection using PoGo type of pins for the RF and power with the Elastomeric type of connector for the digital pins. For this embodiment, a first edge 54 of the card with indexing relief 56 is inserted into a first side 58 of the frame having a securing element 60 received within the relief. The second edge 62 of the card is rotated downward engaging the elastomeric connector in the bottom surface of the card with connecting moiety 38 on the handset PCB. The engagement of securing element 60 with relief 56 in the card provides leverage for engaging both PoGo pins 42 and the elastomeric connector elements. The opposing side edges of the frame (as previously describe with respect to FIG. 3b) provide alignment of the card within the frame for proper engagement of the connectors. In certain embodiments, an additional indexing feature is employed in the relief to align with a corresponding feature in the securing element or first side of the frame for positive positioning of the card as will be described in greater detail subsequently. A retractable securing tab 64 is attached to the frame's second side 66 to engage the second edge of the card after mating with the elastomeric connector to retain the card in the frame. As seen in FIG, 5b, the retractable tab is extended over the top surface of the card adjacent the second side.

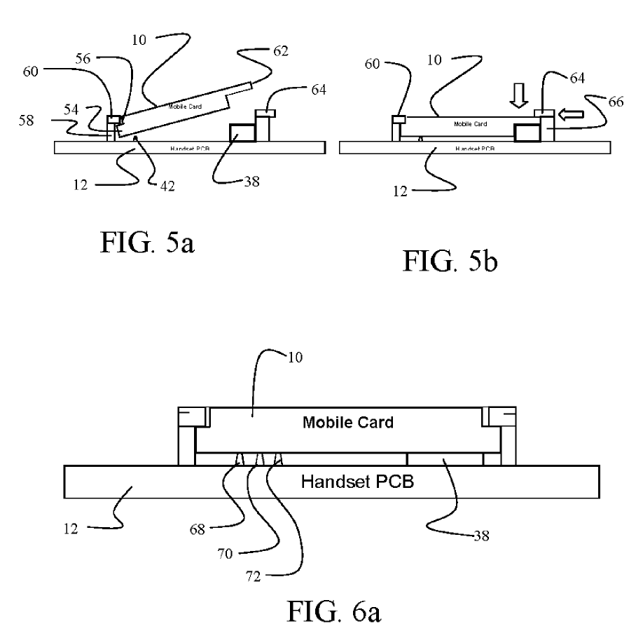

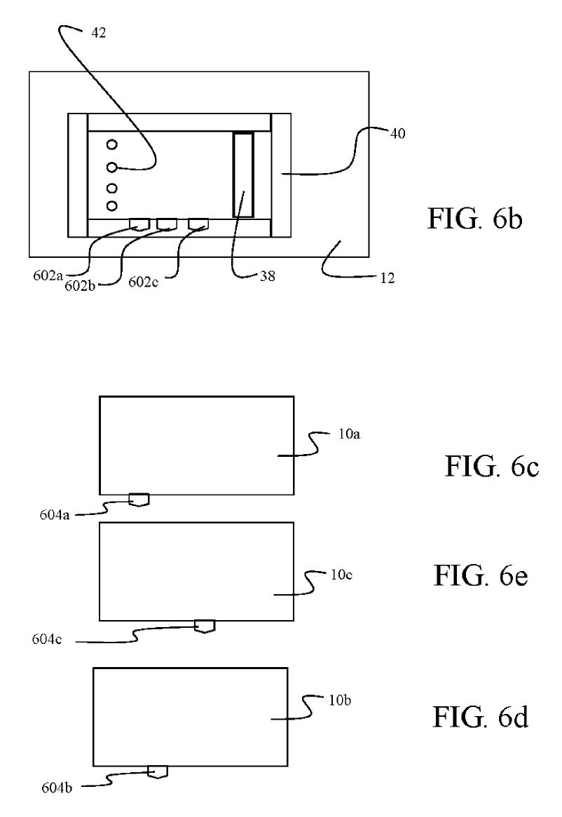

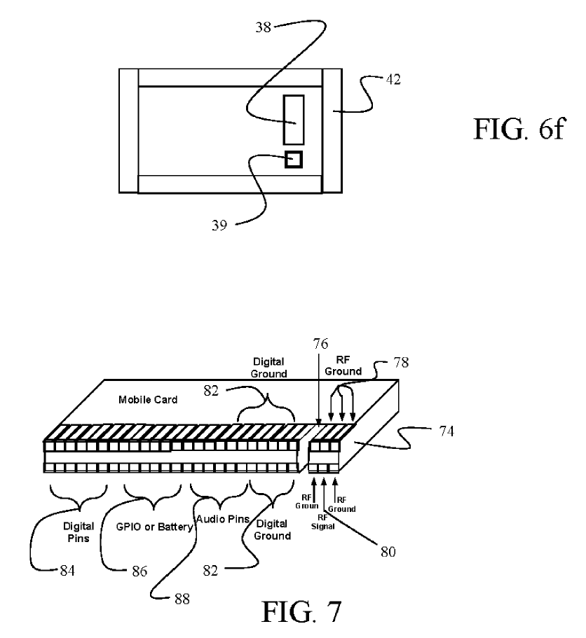

FIG. 6a demonstrates the indexing provided by placement of the PoGo pins on the handset PCB. By providing variable location at positions 68, 70 and 72 only cards having mating moieties of the pins at the appropriate location can be received and connected within the frame. In exemplary embodiments, a first position 68 is employed for cards incorporating GSM communications technology while a second position 70 is used for CDMA cards. A third position 72 is employed for 3G enabled cards. In alternative embodiments, a PHS system is employed.

FIGS. 6b-6e demonstrate indexing employing physical features of the frame and card case. As shown in FIG. 6b, the frame incorporates one or more reliefs 602a, 602b and 602c. A card 110a of FIG. 6c employs a first indexing dimple 604a received in any frame having a corresponding relief; 602a for the embodiment shown in FIG. 6b. Card 110a employs GSM technology or multimode technology as an example. Similarly, card 110b of FIG. 6d, employs an indexing dimple 604b which is arranged for alignment in relief 602b in the frame. Card 110b employs a CDMA protocol interface as an example. Finally, card 110c of FIG. 6e, employs an indexing dimple 604c which is positioned for alignment in relief 602c in the frame. Card 110c employs a PHS protocol communications package. As shown, the frame of FIG. 6b which incorporates all three reliefs, would be employed in a mobile information device which could accept any of the three types of communications protocol. By eliminating one or more of the reliefs from the frame, the mobile information device is limited to specific miniaturized form factor card types. The physical relationship of the frame relief and card case dimple precludes inserting an inappropriate card into the mobile information device.

As an alternative to the use of PoGo connectors for the RF connections to the card described previously with respect to FIGS. 5a and 5b and shown in FIG. 6a, a second elastomeric connector is employed. FIG. 6f shows an alternative embodiment for the mobile card connection frame on the PCB having a first elastomeric connector moiety 38 for the digital signal connection and a second elastomeric connector moiety 39 for RF connection. Tyco Electronics STAX™ LD connectors are employed in exemplary embodiments of the present invention for the digital and RF connector elements described. Positioning of the two elastomeric connectors in linear relation provides for contemporaneous engagement of the two connectors when the card is inserted into the frame. This is particularly advantageous in embodiments such as that shown in FIGS. 5 and 5b where the card is rotated into position.

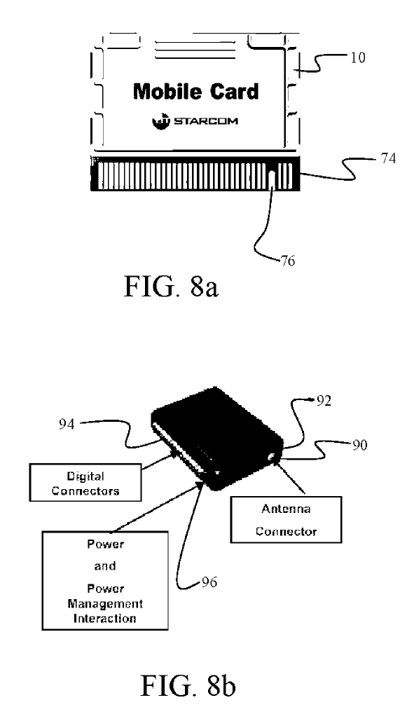

An alternative connector arrangement employed by cards incorporating the present invention is shown in FIG. 7. All pins (RF, audio, digital, power and ground) are provided on one edge type connector 74 (i.e. Samtec MECT-110). The RF pins are arranged in special pattern with a slot 76 intermediate the RF pins and the digital pins and shielding pins 78 surrounding the RF signal pin 80 to ensure proper impedance for the RF circuit for antenna matching. Additionally, all digital pins are arranged in the order that minimize the interference to RF pins. Ground pins 82 are close to RF pins, noisy digital pins 84 are distal from RF the pins, while less noisy GPIO or battery pins 86 and audio pins 88 are centrally arranged on the connector. FIG. 8a shows a pictorial view of an example of the embodiment described with respect to FIG. 7.

A second alternative embodiment similar to that disclosed in FIG. 7 is shown in FIG. 8b wherein the RF antenna connector 90 is located on a separate edge 92 of the card. The digital connectors 94 and power and power management interaction connectors 96 are located on a first edge using a connecting moiety for a blade connector.

The power management circuitry of the card (described previously with respect to FIGS. 2 and 3) interacts with the mobile information device to switch both the card and mobile information Device around different power modes to ensure lowest power consumption. For example, during normal wireless voice call, the mobile information device does not enable the LCD display or powerful application processor, only wireless modem and handset audio peripherals need to be active. In this case, the card turns off the application processor and other non-voice call related mobile information device blocks to save power. In another example, when the mobile information device does not need to enable the wireless function, the mobile information device interacts with the card power management to place the card in standby or deep sleep mode to save power. Thus the mobile information devices enabled by the miniaturized card according to the present invention use power most efficiently and thus enjoying longer battery life.

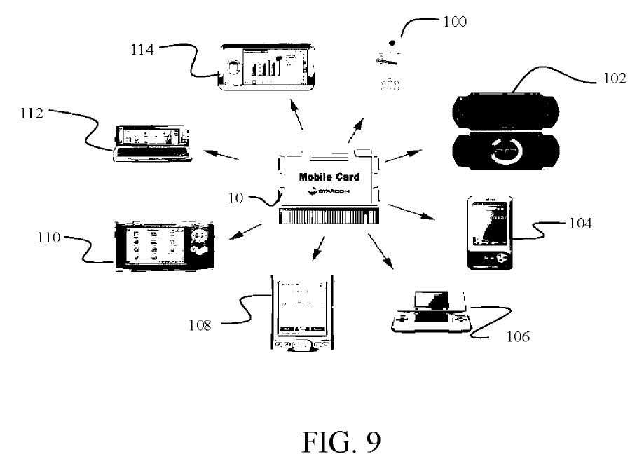

The common architecture of the miniaturized form factor card according to the present invention allows use in a wide variety of mobile information devices such as an MP3 player 100, Sony PSP portable game console 102, mobile phone 104, text messaging device 106, smart phone 108, Global Positioning System (GPS) 110, Personal Digital Assistant (PDA) phone with keyboard 112, and PDA 114 as shown in FIG. 9. The incorporation of communications functions into these devices without requiring design specific circuitry allows rapid incorporation of the communications functions into the innovative designs.

Having now described the invention in detail as required by the patent statutes, those skilled in the art will recognize modifications and substitutions to the specific embodiments disclosed herein. Such modifications are within the scope and intent of the present invention as defined in the following claims.

What is claimed is:

1. A wireless communications card comprising:
an insertable miniaturized form factor card incorporating means for RF transmission and reception and a wireless modem and having a means for indexing and a connector received in a mating moiety in a receiving frame in a mobile information device, user interface components of the mobile information device interconnected to digital functions of the wireless modem and means for RF transmission and reception through the connector.

2. A wireless communications card as defined in claim 1 wherein the connector comprises:
a first connector for digital signal connections; and
a second connector for RF signal connections.

3. A wireless communications card as defined in claim 2 wherein the connector comprises:
a first elastomeric connector for digital signal connections; and
a second connector with spring probe pins for RF signal connections.

4. A wireless communications card as defined in claim 2 wherein the orientation of the first and second connector provide means for indexing for the card.

5. A wireless communications card as defined in claim 2 wherein one of said connectors is provided at a selected one of a plurality of positions for indexing the card for compatibility with the MID.

6. A wireless communications card as defined in claim 1 wherein the connector comprises:
an edge connector having a first plurality of digital pins and a second plurality of RF pins.

7. A wireless communications card as defined in claim 6 wherein the connector further incorporates an indexing slot.

8. A wireless communications card as defined in claim 7 wherein the RF pins separated from the digital pins by the indexing slot.

9. A wireless communications card as defined in claim 6 wherein the RF pins are arranged to provide proper impedance for the antenna.

10. A wireless communications card as defined in claim 6 wherein the plurality of digital pins include digital signal pins, battery connection pins, audio pins and digital ground pins.

11. A wireless communications card as defined in claim 10 wherein the second plurality of RF pins comprises a RF signal pin and a third plurality of RF ground pins, the plurality of RF ground pins substantially surrounding the RF signal pin and the digital ground pins and intermediate the digital signal pins and the second plurality of RF pins.

12. A wireless communications card as defined in claim 11 wherein the indexing slot is located intermediate the plurality of RF pins and the plurality of digital pins.

13. A wireless communications card as defined in claim 1 wherein the wireless modem provides GSM communications protocols.

14. A wireless communications card as defined in claim 1 wherein the wireless modem provides CDMA communications protocols.

15. A wireless communications card as defined in claim 1 wherein the wireless modem provides PHS communications protocols.

16. A wireless communications card as defined in 1 wherein the wireless modem provides UMTS communications protocols.

17. A wireless communications card as defined in claim 1 wherein the wireless modem provides WiMax communications protocols.

18. A wireless communications card as defined in claim 1 wherein the wireless modem provides Digital Video Broadcast—Handheld (DVB-H) communications protocols.

19. A wireless communications card as defined in claim 1 wherein the indexing means comprises an indexing feature on a case of the card and a mating feature on the receiving frame.

20. A wireless communications card comprising:
an insertable miniaturized form factor card incorporating means for RF transmission and reception and a wireless modem and having a means for indexing and a connector received in a mating moiety in a receiving frame in a mobile information device, an applications processor in the mobile information device interconnected to digital functions of the wireless modem and means for RF transmission and reception through the connector.

21. A wireless communications card as defined in claim 1 wherein the vertical dimension of the receiving frame is no greater than the height of the card.

22. A communications system comprising:
a mobile information device having user interface components;
a receiving frame in the mobile information device;
an insertable miniaturized form factor card incorporating means for RF transmission and reception and a wireless modem and having an indexing means and a connector received in a mating moiety in the receiving frame, the user interface components in the mobile information device interconnected to digital functions of the wireless modem and means for RF transmission and reception through the connector.

23. A communications system as defined in claim 22 wherein the connector comprises:
a first connector for digital signal connections; and
a second connector for RF signal connections.

24. A communications system as defined in claim 23 wherein the connector comprises:
a first elastomeric connector for digital signal connections; and
a second connector with spring probe pins for RF signal connections.

25. A communications system as defined in claim 23 wherein the orientation of the first and second connector provide means for indexing for the card.

26. A communications system as defined in claim 23 wherein one of said connectors is provided at a selected one of a plurality of positions for indexing the card for compatibility with the MID.

27. A communications system as defined in claim 22 wherein the connector comprises:
an edge connector having a first plurality of digital pins and a second plurality of RF pins.

28. A communications system as defined in claim 27 wherein the connector further incorporates an indexing slot.

29. A communications system as defined in claim 28 wherein the RF pins separated from the digital pins by the indexing slot.

30. A communications system as defined in claim 27 wherein the RF pins are arranged to provide proper impedance for the antenna.

31. A communications system as defined in claim 27 wherein the plurality of digital pins include digital signal pins, battery connection pins, audio pins and digital ground pins.

32. A communications system as defined in claim 31 wherein the second plurality of RF pins comprises a RF signal pin and a third plurality of RF ground pins, the plurality of RF ground pins substantially surrounding the RF signal pin and the digital ground pins and intermediate the digital signal pins and the second plurality of RF pins.

33. A communications system as defined in claim 32 wherein the indexing slot is located intermediate the plurality of RF pins and the plurality of digital pins.

34. A communications system as defined in claim 22 wherein the wireless modem provides GSM communications protocols.

35. A communications system as defined in claim 22 wherein the wireless modem provides CDMA communications protocols.

36. A communications system as defined in claim 22 wherein the wireless modem provides PHS communications protocols.

37. A communications system as defined in claim 22 wherein the wireless modem provides UMTS communications protocols.

38. A communications system as defined in claim 22 wherein the wireless modem provides WiMax communications protocols.

39. A communications system as defined in claim 22 wherein the wireless modem provides Digital Video Broadcast—Handheld (DVB-H) communications protocols.

40. A communications system as defined in claim 22 wherein the indexing means comprises an indexing feature on a case of the card and a mating feature on the receiving frame.

41. A communications system comprising:
a mobile information device having user interface components;
a receiving frame in the mobile information device;
an insertable miniaturized form factor card incorporating means for RF transmission and reception and a wireless modem and having a means for indexing and a connector received in a mating moiety in a receiving frame in a mobile information device, and having an applications processor in the mobile information device interconnected to digital functions of the wireless modem and means for RF transmission and reception through the connector.

42. A communications system as defined in claim 22 wherein the miniaturized form factor card further includes a means for power management, said power management means interfacing with the applications processor through the connector.

43. A wireless communications card as defined in claim 2 wherein the connector comprises:
a first elastomeric connector for digital signal connections; and
a second elastomeric connector for RF signal connections.

44. A wireless communications card as defined in claim 43 wherein the first elastomeric connector and a second elastomeric connector are arranged linearly for contemporaneous engagement upon insertion of the card into the frame.

45. A communications system as defined in claim 22 wherein the mobile information device user interface functions include a keyboard and said connector on the insertable miniaturized form factor card includes a matrix of pins having a standard interface to the keyboard for mobile information device interchangeability.

46. A communications system as defined in claim 45 wherein the matrix of pins is 5×5 and provides for function definition of 25 corresponding keys on the mobile information device.

47. A communications system as defined in claim 22 wherein the mobile information device incorporates an applications processor and includes means for transmitting predetermined commands relating to wireless communications functionality to the miniaturized form factor card.

48. A communications system as defined in claim 47 wherein the transmitting means comprises an AT command interface.
